(19) United States
(12) Patent Application Publication
(10) Pub. No.: US 2013/0341769 A1
(43) Pub. Date: Dec. 26, 2013

(54) ALUMINIUM OXIDE-BASED METALLISATION BARRIER

(71) Applicants: Ingo Koehler, Reinheim (DE); Oliver Doll, Dietzenbach (DE); Werner Stockum, Reinheim (DE); Sebastian Barth, Darmstadt (DE)

(72) Inventors: Ingo Koehler, Reinheim (DE); Oliver Doll, Dietzenbach (DE); Werner Stockum, Reinheim (DE); Sebastian Barth, Darmstadt (DE)

(73) Assignee: MERCK PATENT GMBH, Darmstadt (DE)

(21) Appl. No.: 14/004,074

(22) PCT Filed: Feb. 9, 2012
(86) PCT No.: PCT/EP2012/000590

§ 371 Date: Sep. 9, 2013

(30) Foreign Application Priority Data
Mar. 8, 2011 (EP) 11001920.5
Mar. 8, 2011 (EP) 11001921.3
Aug. 26, 2011 (EP) 11006971.3
Sep. 6, 2011 (EP) 11007205.5
Sep. 6, 2011 (EP) 11007207.1

(51) Int. Cl. H01L 31/0216

(52) U.S. Cl. CPC H01L 31/02167
USPC 257/632; 438/778

(57) ABSTRACT

The present invention relates to aluminium oxide-based passivation layers which simultaneously act as diffusion barrier for underlying wafer layers against aluminium and other metals. Furthermore, a process and suitable compositions for the production of these layers are described.

The present invention relates to aluminium oxide-based passivation layers which simultaneously act as diffusion barrier for underlying wafer layers against aluminium and other metals. Furthermore, a process and suitable compositions for the production of these layers are described.

Ever-thinner solar wafers (current thickness 200-180 μm with a strong trend towards 160 μm) are causing ever more-pressing problems in conventional full-area metallisation on the back. On the one hand, the surface recombination speed in the strongly aluminium-doped layer is very high (typically 500-1000 cm/s) and cannot be reduced further as desired by means of the existing conventional technology. The consequence is a lower power output compared with more advanced, but also more expensive concepts, which is principally evident from lower short-circuit currents and reduced open terminal voltage. On the other hand, the full-area metallisation and the requisite firing process for this purpose, which takes place at peak temperatures of between 800° C. and 950° C., result, owing to different coefficients of thermal expansion, in considerable stresses at the interface between the back electrode and the silicon substrate and so-called “bow” which sometimes propagates therein. This can typically be up to 6 mm in finished solar cells. This “bow” has an extremely disadvantageous effect during subsequent module assembly of the solar cells since a significantly increased breakage rate during manufacture is associated therewith.

Novel solar-cell concepts have been considerably modified compared with the conventional manufacture of solar cells and modules. This has advantageous and far-reaching effects. On the one hand, most concepts considerably increase the average efficiency achieved by the individual cells and modules. On the other hand, most concepts result in a lower material requirement for silicon (which, in the form of wafers, can make up up to 70% of the costs in the manufacture of solar cells).

In contrast to the conventional solar cell, which has virtually full-area metallisation on the back, some of the novel cell concepts are based on local metallisation of the back, which is generally taken to mean the so-called local back surface field (LBSF). LBSF is the core technology for optimisation of the efficiency fractions to be obtained on the back of the solar cell. It is thus the key for maximisation of basic solar-cell parameters, such as those of the short-circuit current and/or the open terminal voltage. At the same time, and this is possibly more important from the point of view of industrial mass production of solar cells, it opens up the possibility of circumventing or avoiding negative phenomena, such as, for example, the “bow” already formulated in the introduction, i.e. the bending of solar cells. These are predominantly technical production and technologically induced problems.

The concept of LBSF is depicted in FIG. 1. FIG. 1 shows the diagram of the architecture of a highly efficient solar cell in accordance with the PERC concept (cf. text), more precisely a solar cell with passivated (selective) emitter and local (point) contacts on the back (LBSF) [1].

Generation of the LBSF represents the basic principle of all technologies which are based or founded on the “passivated emitter and rear cell” (PERC) concept.

In order to achieve this selective structuring or in order to generate the LBSF structure, various technological approaches are currently being followed. All approaches have the common feature that the surface of the silicon wafer, in this case the back, must be locally structured in order to define and generate an arbitrarily repeating arrangement of, for example, point-contact holes. To this end, methods are necessary which allow structuring of the substrates, on the one hand inherently during production or on the other hand subsequently; in this case, “subsequently” refers to the structuring of the mask technology used for definition of the local contacts or of the mask itself.

By far the most frequent, in particular in the production of solar cells, is the use of dielectric layers, masks and/or layer stacks, which can usually be applied to the surfaces in question with the aid of physical and/or chemical vapour deposition, PVD and CVD methods. Suitable dielectric layers here are generally silicon oxides and silicon nitrides or layer stacks comprising the two materials. The above-mentioned dielectrics, which can be referred to as more classical, have recently been supplemented by others. These can be, for example: aluminium oxides, but also silicon oxynitrides. Furthermore, silicon carbide, silicon carbonitride (SiCxNy) and layer stacks comprising amorphous silicon (a-Si) and silicon nitride are currently being investigated for their suitability for the coating of the back of the solar wafer. All the said materials and material systems (layer stacks) must fulfil two functions when they are used, namely act simultaneously on the one hand as (diffusion) mask and on the other hand as (electronic) passivation layer. The necessity for a passivation layer on the back arises from the architecture of the LBSF solar cell. The efficiency potential of the LBSF solar cell compared with the conventional standard solar cell with full-area metallisation on the back is essentially based on the possibility of significant reduction in the surface recombination speed, in this case on the back, of the excess charge-carrier density, generated as a consequence of light absorption, at the wafer surface compared with the value mentioned in the introduction for the standard Al BSF solar cell. Compared with this regime of the surface recombination speed, suitable passivation layers and layer systems can achieve values down into the region of single-figure or low double-figure surface recombination speeds, which corresponds approximately to a reduction by a factor of 100.

Thus, one of the LBSF approaches is based on the use of a resist layer comprising wax, which is printed onto the back, which is provided with a dielectric, and is subsequently structured using concentrated hydrofluoric acid. After removal of the wax layer, a metal paste is printed on over the entire surface. This cannot penetrate the dielectric during the firing process, but can do so at the points where the silicon is exposed owing to the structuring step [2].

The LBSF cell can in principle be implemented by means of at least three technologies (except for the example above).

These technologies must satisfy two conditions:
a) they must be able to generate local ohmic contacts in the silicon and
b) these ohmic contacts must ensure the transport of majority charge carriers from the base, through the formation of the back surface field, which functions as a type of electronic mirror, but suppress the transport of minority charge carriers to these contacts.

The latter is facilitated by the back surface field, the electronic mirror. In order to generate this electronic “mirror”, which is located below the ohmic contacts, three types of implementation are conceivable if starting from p-doped base material, which will be outlined briefly below:

1.The first method is carried out by local increased post-doping of the regions of the later contact points with boron before metallisation, or alternatively by local contact and LBSF formation with the aid of aluminium paste. This first implementation possibility requires the use of mask technology, in this case of a diffusion mask, which suppresses the full-area doping of the back, but also of the front, with in this case boron. Local holes in the mask enable the creation of the boron-doped back surface field in the silicon on the back.

However, this technology also requires the production of the diffusion mask, the production of the local structuring of the diffusion mask and removal thereof, since this boron-interspersed diffusion mask itself cannot have a passivating action, and the creation of a layer which has a passivating action for the surface and, if necessary, encapsulation thereof. Even this brief outline shows the difficulties which usually underlie this approach, besides technological problems of a general nature: time, industrial throughput and thus ultimately the costs of implementation.

2. The second possibility consists in the production of so-called “laser fired contacts”, LFCs. In this case, a passivating layer, usually a silicon oxide layer, is generated on the back of the silicon wafer. This oxide layer is covered with a thin layer of aluminium (layer thickness >=2 μm) by means of vapour-deposition methods. A dot pattern is subsequently inscribed on the back of the wafer using a laser. During the bombardment, the aluminium is melted locally, penetrates the passivation layer and subsequently forms an alloy in the silicon. During the alloy formation of the Al in the silicon, the LBSF forms at the same time. The technology for the production of an LBSF solar cell by means of the LFC process is distinguished by high process costs for the deposition of the vapour-deposited aluminium layers, meaning that the possibility of industrial implementation of this concept has not yet been definitively answered.

3. The third possibility arises from the exclusive use of aluminium paste, by means of which both the LBSF formation and also the contact formation can be achieved in a firing step in a similar manner to the formation of full-area Al BSF structures. This principle can frequently be found in the literature under the term “i-PERC”: this involves a screen-printed PERC solar cell, which was developed by the IMEC research institute and in which the LBSF structure is formed exclusively by means of a conventional aluminium paste, which has become established in industry, is easily matched to the requirements and is employed for full-area metallisation on the back. The prerequisite for this is the creation of the hole for local contacts on the back of a layer which is sufficiently stable or diffusion-resistant to the firing of aluminium paste and to which the paste can adhere sufficiently without delamination. Furthermore, the back which remains must be electronically passivated.

The diffusion-barrier layer ideally fulfils both functions. However, not all above-mentioned materials and layer systems are suitable as diffusion-barrier layers of this type. Silicon oxide is not resistant to penetration by aluminium paste. In technical jargon, this process is called “spiking through”. This lack of resistance of the silicon oxide layer during firing is caused by the alumothermal process at high temperatures; to be precise, silicon oxide is less thermodynamically stable than aluminium oxide. This means that the aluminium diffusing in during the firing can reduce to aluminium oxide by reaction with silicon oxide, with the silicon oxide simultaneously being reduced to silicon. The silicon formed subsequently dissolves in the stream of aluminium paste. By contrast, silicon nitride is distinguished by adequate resistance to “spiking through” of the aluminium paste. Silicon nitride, although suitable as passivation material, cannot, however, function as passivation material and diffusion-barrier layer since the problem of “parasitic shunting” is frequently observed at local contacts. “Parasitic shunting” is generally taken to mean the formation of a thin inversion layer or a thin inversion channel located directly at the interface between silicon nitride and p-doped base. The polarity of this region is reversed to give an n-conducting zone, which, if it comes into contact with the local contacts on the back, injects majority charge carriers (electrons) into the majority charge-carrier stream of the point contacts (holes). The consequence is recombination of the charge carriers and thus a reduction in the short-circuit current and the open terminal voltage. For this reason, layer systems comprising a few nanometres of silicon oxide covered with up to 100 nm of silicon nitride are frequently used for LBSF solar cells. Alternative layer systems can be composed of the following layer stacks: SiOₓ/SiNₓ/SiNₓ, SiOₓ/SiOₓNₓ/SiNₓ, SiOₓN_{y}/SiNₓ/SiNₓ, SiOₓ/AlOₓ, AlOₓ/SiNₓ, etc. These layer stacks are applied to the wafer surface in a conventional manner by means of PVD and/or CVD methods and are thus system-inherently expensive and in some cases unsuitable for industrial production [cf., for example, coating with aluminium oxide by means of “atomic layer deposition” (ALD)].

The industrial implementation of i-PERC, or rather the screen-printed LBSF concept, appears to come quite close to the requirements of industrial implementation. Further factors favouring implementation of this concept would be both inexpensive process performance of the absolutely necessary passivation on the back and also simple deposition of a diffusion-barrier layer against “spiking through” of the aluminium paste. Ideally, it would be possible to implement both concepts in only one process step, preferably from just one individual layer of sufficient thickness. In this connection, it would furthermore be desirable to be able to replace the complex PVD and CVD technologies with much simpler process techniques. In particular, it would be desirable to be able to produce such layers by simple printing of corresponding starting compositions, since this would represent a considerable simplification in industrial implementation of the LBSF concept and would considerably reduce costs.

Based on the principle of the PERC cell, the literature contains some highly promising concepts which increase the efficiency and reduce the cell breakage rate during manufacture. For example, the PASHA concept (passivated on all sides H-patterned) may be mentioned here (cf. [3]). In this concept, hydrogen-rich silicon nitride, which has excellent passivation properties both on strongly n-doped material and on weakly p-doped material, is applied to both sides of the solar wafers. Metal paste is subsequently printed on locally in the areas of the contacts on the back and penetrates the silicon nitride in the subsequent firing process. A disadvantage in this process is that penetration points are not pre-specified for the metal paste. The paste consequently penetrates at all points where it comes into contact with the nitride. A further disadvantage are the costs arising with the nitride coating. The standard process for the application of nitride layers is “plasma enhanced physical vapour deposition” (PEPVD). In this technique, ammonia and silane are deposited on the silicon substrate in the gas phase in the form of silicon nitride when the reaction is complete. This process is time-consuming and thus expensive, where the costs are influenced, inter alia, by the use of high-purity gases which are critical from occupational safety points of view (NH₃ and SiH₄).

In addition, a new selective printing technique is required in order to establish the PASHA concept, since the production lines to date are designed for full-area printing.

A further example which combines the technological advantages of the PERC concept with the advantage of “penetrating” metallisation (metal wrap through (MWT)), in which all contacts facing the outside are on the back, enabling more sunlight to penetrate into the cell on the front, is the concept of the “all sides passivated and interconnected at the rear” solar cell (ASPIRe) (cf. [4]). In this cell principle too, the back is passivated by silicon nitride, which is accompanied by the advantages and disadvantages already mentioned above.

The structure of a solar cell with integrated MWT architecture which is passivated on all sides and interconnected at the rear {(ASPIRe) [5]} is shown in FIG. 2 for illustration. The contacts on the back are depicted as black elements in the figure. These contacts on the back in each case contain the LBSF areas.

### [1] A. Goetzgerger, V. U. Hoffmann, Photovoltaic Energy Generation, Springer, 2005

### [2] F. S. Grasso, L. Gautero, J. Rentsch, R. Preu, R. Lanzafame, Presented at the 25th European PV Solar Energy Conference and Exhibition, 2010, Valencia, Spain

### [3] I. Romijn, I. Cesar, M. Koppes, E. Kossen, A. Weeber, Presented at the IEEE Photovoltaic Specialists Conference, 2008, San Diego, USA

[4] M. N. van den Donker, P. A. M. Wijnen, S. Krantz, V. Siarheyeva, L. JanBen, M. Fleuster, I. G. Romijn, A. A. Mewe, M. W. P. E. Lamers, A. F. Stassen, E. E. Bende, A. W. Weeber, P. van Eijk, H. Kerp, K. Albertsen, Proceedings of the 23rd European Photovoltaic Solar Energy Conference, 2008, Valencia, Spain

### [5] I. G. Romijn, A. A. Mewe, E. Kossen, I. Cesar, E. E. Bende, M. N. van den Donker, P. van Eijk, E. Granneman, P. Vermont, A. W. Weeber, 2010, Valencia, Spain

### OBJECT

The object of the present invention is therefore to provide a process and a composition which can be employed therein by means of which a dielectric layer, by means of which both a passivation layer and also a barrier layer against “spiking through” of the aluminium during the firing process can be produced, can be applied inexpensively and in a simple manner to silicon wafers on the basis of a sol-gel process. It should preferably be possible for this layer to be applied in a single process step by simple selective printing-on of the composition required for this purpose.

### BRIEF DESCRIPTION OF THE INVENTION

The object is achieved, in particular, by a process for the production of a dielectric layer which acts as passivation layer and diffusion barrier against aluminium and/or other related metals and metal pastes, in which an aluminium oxide sol or an aluminium oxide hybrid sol in the form of an ink or paste is applied over the entire surface or in a structured manner and is compacted and dried by warming at elevated temperatures, forming amorphous Al₂O₃ and/or aluminium oxide hybrid layers. In this way, amorphous Al₂O₃ and/or aluminium oxide hybrid layers having a thickness of <100 nm are formed. In order to achieve a greater layer thickness of amorphous Al₂O₃ and/or aluminium oxide hybrid of at least 150 nm by this process, the aluminium oxide sol or aluminium oxide hybrid sol can be applied and dried a number of times in a particular embodiment of the process according to the invention. After application of the sol, the drying is carried out at temperatures between 300 and 1000° C., preferably in the range between 350 and 450° C. Good layer properties are achieved if this drying is carried out within a time of two to five minutes. Particularly good barrier-layer properties arise if the layer(s) applied and dried in accordance with the invention is (are) passivated by subsequent annealing at 400 to 500° C. in a nitrogen and/or forming-gas atmosphere.

Doped aluminium oxide or aluminium oxide hybrid layers can advantageously be applied to the treated substrate layers by the process according to the invention by application of aluminium oxide inks or aluminium oxide pastes based on the sol-gel process which comprise at least one precursor, serving for doping, for the formation of an oxide of boron, gallium, silicon, germanium, zinc, tin, phosphorus, titanium, zirconium, yttrium, nickel, cobalt, iron, cerium, niobium, arsenic or lead. In a particular embodiment of the process according to the invention, boron doping of an underlying silicon substrate layer is carried out by drying an applied layer of a boron-containing aluminium oxide ink or paste at elevated temperature, and in a further embodiment boron doping is carried out with emitter formation in the silicon. In another embodiment of the process, phosphorus doping of an underlying silicon substrate layer is carried out by drying an applied layer of a phosphorus-containing aluminium oxide ink or paste at elevated temperature.

In particular, the object of the present invention is achieved by the provision of a dielectric aluminium oxide layer having passivation properties for p-doped base layers, preferably silicon base layers, which can be produced in a simple manner by the process according to the invention. A particular embodiment of the process according to the invention enables the production of dielectric layers which act as diffusion barrier against aluminium and other related metals.

### DETAILED DESCRIPTION OF THE INVENTION

Experiments have shown that a corresponding dielectric can be produced on silicon wafers in a sol-gel process, where pure aluminium oxide sol or aluminium oxide hybrid sol can be used for this purpose. A dielectric produced in adequate layer thickness by this process advantageously exhibits, after suitable thermal pre-treatment, diffusion resistance to “spiking through” by aluminium compared with conventional screen-printable aluminium-containing metal pastes which are usually used for the production of contacts on crystalline silicon solar cells.

Since the compositions used for the production of the dielectric layer are printable, they can be applied not only over the entire wafer surface, but can also be printed in a structured manner, making subsequent structuring by etching the dielectric, which is usually necessary, for example in order to generate local contact holes, superfluous. In addition, the dielectric produced in accordance with the invention is distinguished by an excellent capacity for the passivation of p-doped silicon wafer surfaces.

Application of a thin layer of aluminium oxide which is structured in accordance with requirements to the back of silicon wafers enables locally opened, i.e. non-masked, areas to be metallised and provided with contacts, whereas the masked, i.e. coated, surface is protected against undesired contact formation by the metallisation. The aluminium oxide layer is produced by a sol-gel process, which facilitates the application of a stable sol by means of inexpensive printing technology. The sol printed-on in this way is converted into the gel state by means of suitable methods, such as, for example, warming, and compacted in the process. The production of the aluminium layer by sol-gel processes can be carried out by the processes described in the European patent applications with the application numbers 11001921.3 and 11001920.5. The disclosure content of these two applications is hereby incorporated into this application.

The aluminium oxide layer not only acts as barrier layer, but also additionally exhibits excellent passivation properties for the p-doped base, meaning that no further cleaning and production steps are necessary after the firing process.

The process according to the invention can preferably be carried out using sol-gel-based inks and/or pastes, which enable the formation of dielectric aluminium oxide or aluminium oxide hybrid layers having a barrier action, by means of which diffusion of metallic aluminium and/or other comparable metals and metal pastes which can form a low-melting (<1300° C.) alloy with silicon can be prevented. The dielectric aluminium oxide or aluminium oxide hybrid layers formed in the process according to the invention accordingly act as diffusion barrier.

Particular preference is given to the use of sterically stabilised inks and/or pastes, as are described and characterised in the patent applications cited above, for the formation of Al₂O₃ coatings and mixed Al₂O₃ hybrid layers in the process according to the invention.

Suitable hybrid materials for this use are, in particular, mixtures of Al₂O₃ with the oxides of boron, gallium, silicon, germanium, zinc, tin, phosphorus, titanium, zirconium, yttrium, nickel, cobalt, iron, cerium, niobium, arsenic and lead, where the inks and/or pastes are obtained by the introduction of the corresponding precursors into the system.

After the inks and/or pastes according to the invention have been applied to the wafer surfaces in the desired manner, they are dried at elevated temperatures in order to form the barrier layers. This drying is carried out at temperatures between 300 and 1000° C., with amorphous Al₂O₃ and/or aluminium oxide hybrid layers forming. At these temperatures, residue-free drying with formation of the desired layers takes place within a time of <5 minutes at a layer thickness of <100 nm. The drying step is preferably carried out at temperatures in the range 350-450° C. In the case of thicker layers, the drying conditions must be adapted correspondingly. However, it should be noted here that hard, crystalline layers (cf. corundum) form on heating from 1000° C.

The dried Al₂O₃ (hybrid) layers obtained by drying at temperatures <500° C. can subsequently be etched using most inorganic mineral acids, but preferably by HF and H₃PO₄, and by many organic acids, such as acetic acid, propionic acid and the like. Simple post-structuring of the layer obtained is thus possible.

Mono- or multicrystalline silicon wafers (HF- or RCA-cleaned), sapphire wafers, thin-film solar modules, glasses coated with functional materials (for example ITO, FTO, AZO, IZO or the like) and uncoated glasses, steel elements and alloyed derivatives thereof, and other materials used in microelectronics can be coated in a simple manner with these inks and/or pastes according to the invention described here.

In accordance with the invention, the sol-gel-based formulations, inks and/or pastes are printable. For the various applications, it is possible for the person skilled in the art to modify the properties, in particular the rheological properties, of the formulations and to match them within broad limits to the respectively necessary requirements of the printing method to be used, so that the paste formulations can be applied both selectively in the form of extremely fine structures and lines in the nm range and also over the entire surface. Suitable printing methods are: spin or dip coating, drop casting, curtain or slot-dye coating, screen or flexo printing, gravure or ink-jet or aerosol-jet printing, offset printing, micro contact printing, electrohydrodynamic dispensing, roller or spray coating, ultrasonic spray coating, pipe jetting, laser transfer printing, pad printing, rotation screen printing and others.

Application of aluminium oxide inks and/or aluminium oxide pastes based on the sol-gel process enables excellent surface passivation of silicon wafers (especially of p-type wafers) to be achieved. The charge-carrier lifetime is already increased here by application of a thin layer of Al₂O₃ with subsequent drying. The surface passivation of the layer can be considerably increased by subsequent annealing at 400-500° C. in a nitrogen and/or forming-gas atmosphere.

The use of a boron-containing aluminium oxide ink and/or paste at the same time as drying at elevated temperatures enables boron doping of the underlying silicon to be achieved. This doping results in an “electronic mirror” on the back of the solar cell, which can have a positive effect on the efficiency of the cell. The aluminium oxide here simultaneously has a very good surface-passivating action on the (strongly) p-doped silicon layer.

The use of a boron-containing aluminium oxide ink and/or paste can likewise be employed for doping with emitter formation in the silicon; more precisely, the doping results in p-doping on n-type silicon. At the same time, the aluminium oxide here has a very good surface-passivating action on the p-doped emitter layer.

As already mentioned above, suitable sol-gel inks, as described in the European patent application with the application number 11001920.5, can be used for the production of the aluminium oxide layers according to the invention. The use of such inks enables the formation of smooth layers which are stable in the sol-gel process and are free from organic contamination after drying and heat treatment at in a combined drying and heat treatment at temperatures preferably below 400° C.

The inks are sterically stabilised Al₂O₃ inks having an acidic pH in the range 4-5, preferably <4.5, which comprise alcoholic and/or polyoxylated solvents. Compositions of this type have very good wetting and adhesion properties for SiO₂- and silane-terminated silicon wafer surfaces.

These ink-form aluminium sols can be formulated using corresponding alkoxides of aluminium, such as aluminium triethoxide, aluminium triisopropoxide and aluminium tri-sec-butoxide, or readily soluble hydroxides and oxides of aluminium. These aluminium compounds are dissolved in solvent mixtures. The solvents here can be polar protic solvents and polar aprotic solvents, to which non-polar solvents may in turn be added in order to match the wetting behaviour to the desired conditions and properties of the coatings. The description of the above-mentioned application lists a very wide variety of examples of the corresponding solvents.

Solvents which may be present in the inks are mixtures of at least one low-boiling alcohol, preferably ethanol or isopropanol, and a high-boiling glycol ether, preferably diethylene glycol monoethyl ether, ethylene glycol monobutyl ether or diethylene glycol monobutyl ether. However, other polar solvents, such as acetone, DMSO, sulfolane or ethyl acetate and the like, may also be used. The coating property can be matched to the desired substrate through their mixing ratio. Furthermore, the inks which can be employed comprise water if aluminium alkoxides have been employed for the sol formation. The water is necessary in order to achieve hydrolysis of the aluminium nuclei and pre-condensation thereof, and in order to form a desired impermeable, homogeneous layer, where the molar ratio of water to precursor should be between 1:1 and 1:9, preferably between 1:1.5 and 1:2.5.

Furthermore, the addition of organic acid, preferably acetic acid, is necessary, causing the alkoxides liberated to be converted into the corresponding alcohols. At the same time, the added acid catalyses the precondensation and the crosslinking, commencing therewith, of the aluminium nuclei hydrolysed in solution. The above-mentioned application lists many suitable acids.

The addition of suitable acids or acid mixtures simultaneously allows stabilisation of the ink sol to take place. However, complexing and/or chelating additives may also deliberately be added to the sol for this purpose. Corresponding complexing agents are revealed by the above-mentioned application. Steric stabilisation of the inks is effected here by mixing with hydrophobic components, such as 1,3-cyclohexadione, salicylic acid and structural relatives thereof, and moderately hydrophilic components, such as acetylacetone, dihydroxybenzoic acid, trihydroxybenzoic acid and structural relatives thereof, or with chelating agents, such as ethylenediaminetetraacetic acid (EDTA), diethylenetriaminepentaacetic acid (DETPA), nitrilotriacetic acid (NTA), ethylenediaminetetramethylenephosphonic acid (EDTPA), diethylene-triaminepentamethylenephosphonic acid (DETPPA) and structurally related complexing agents or chelating agents.

Furthermore, further additives for adjusting the surface tension, viscosity, wetting behaviour, drying behaviour and adhesion capacity can be added to the aluminium sol. Inter alia, it is also possible to add particulate additives for influencing the rheological properties and drying behaviour, such as, for example, aluminium hydroxides, aluminium oxides, silicon dioxide, or, for the formulation of hybrid sols, oxides, hydroxides, alkoxides of the elements boron, gallium, silicon, germanium, zinc, tin, phosphorus, titanium, zirconium, yttrium, nickel, cobalt, iron, cerium, niobium, arsenic, lead, inter alia, where oxides, hydroxides, alkoxides of boron and phosphorus have a doping effect on semiconductors, in particular on silicon layers.

The layer-forming components are preferably employed in suitable ink compositions in a ratio such that the solids content of the inks is between 0.5 and 10% by weight, preferably between 1 and 5% by weight.

The residue-free drying of the inks after coating of the surfaces results in amorphous Al₂O₃ layers, where the drying is carried out at temperatures between 300 and 1000° C., preferably at about 350° C. In the case of suitable coating, the drying is carried out within a time of <5 minutes, giving a layer thickness of <100 nm. If thicker layers are desired, the drying conditions must be varied correspondingly. Al₂O₃ (hybrid) layers which have been dried at temperatures <500° C. can be etched and structured through the use of most inorganic mineral acids, but preferably by HF and H₃PO₄, and by many organic acids, such as acetic acid, propionic acid and the like. Suitable substrates for coating with the corresponding inks are mono- or multicrystalline silicon wafers (cleaned with HF or RCA), sapphire wafers, thin-film solar modules, glasses coated with functional materials (for example ITO, FTO, AZO, IZO or the like), uncoated glasses, and other materials used in microelectronics. In accordance with the substrates used, the layers formed through the use of the inks can serve as diffusion barrier, printable dielectric, electronic and electrical passivation or antireflection coating.

Inks used for the production of the barrier layers in the form of hybrid materials comprising simple and polymeric boron and phosphorus oxides and alkoxides thereof can be used for the simultaneous inexpensive full-area and local doping of semiconductors, preferably of silicon.

As already stated above, correspondingly modified pastes can additionally also be used instead of the inks described, depending on the conditions present, for the production of the barrier layers, as described in the European patent application with the application number 11001921.3.

The same starting compounds of aluminium and the same solvents and additives can be used for the preparation of the sol-gel pastes, but, in order to adjust the paste properties, suitable thickeners may be present and/or a correspondingly higher solids content may be present. Details of corresponding pastes are described in detail in the corresponding patent application. The same compounds of aluminium can be employed as precursors for the formulation of the aluminium sols; in particular, all organic aluminium compounds which are suitable for the formation of Al₂O₃ in the presence of water under acidic conditions at a pH in the range from about 4-5 are suitable as precursors in paste formulations.

Corresponding alkoxides are preferably also dissolved in a suitable solvent mixture here. This solvent mixture can be composed both of polar protic solvents and also polar aprotic solvents, and mixtures thereof. Corresponding solvent mixtures are described in the patent application indicated. Like corresponding inks described above, the paste formulations are stabilised by the addition of suitable acids and/or chelating or complexing agents. The rheological properties can be influenced and suitable paste properties, such as structural viscosity, thixotropy, flow point, etc., can be adjusted by the addition of suitable polymers. Furthermore, particulate additives can be added in order to influence the rheological properties. Suitable particulate additives are, for example, aluminium hydroxides and aluminium oxides, silicon dioxide, by means of which the dry-film thicknesses resulting after drying and the morphology thereof can be influenced at the same time. In particular, for the preparation of the pastes which can be employed in accordance with the invention, the layer-forming components are employed in such a ratio to one another that the solids content of the pastes is between 9 and 10% by weight. As in the case of the use of the inks described above, the pastes can be applied to the entire surface of the substrates to be treated or in a structured manner with high resolution down to the nm region by suitable methods and dried at suitable temperatures. These pastes are preferably applied by printing by means of flexographic and/or screen printing, particularly preferably by means of screen printing.

The sol-gel paste formulations can be used for the same purposes as the inks described above.

The use of these pastes enables Al₂O₃ layers to be obtained which can serve as sodium and potassium diffusion barrier in LCD technology. A thin layer of Al₂O₃ on the cover glass of the display can prevent the diffusion of ions from the cover glass into the liquid-crystalline phase, enabling the lifetime of the LCDs to be increased considerably.

### LIST OF FIGURES

FIG. 1: Architecture of a highly efficient solar cell in accordance with the PERC concept (cf. text). The diagram shows a solar cell with passivated (selective) emitter and local (point) contacts on the back (LBSF) [1].

FIG. 2: Architecture of a solar cell with integrated MWT architecture which is passivated on all sides and interconnected at the rear, (ASPIRe) [5]. The black elements in the figure represent the contacts on the back, which each contain LBSF regions.

FIG. 3: Photographs of the wafer pieces before metallisation (Example 2).

FIG. 4: Photomicrographs of the surface after the etch treatment in accordance with Example 2; the photographs show the surfaces of SiO2-coated wafers after firing and subsequent etching-off of the aluminium paste (a 258 nm of SiO₂; b 386 nm of SiO₂; c 508 nm of SiO₂; d 639 nm of SiO₂; e no barrier; f reference without metal paste).

FIG. 5: Photographs of the wafer pieces from Example 3 before metallisation.

FIG. 6: Photomicrographs of the surface after the etch treatment in Example 3. The photomicrographs show the surfaces of Al₂O₃-coated wafers after firing and subsequent etching-off of the aluminium paste (a 113 nm of Al₂O₃; b 168 nm of Al₂O₃; c 222 nm of Al₂O₃; d reference wafer without metal paste).

FIG. 7: ECV measurements of the samples coated with various layer thicknesses in Example 3, an uncoated reference sample and a reference processed at the same time, but not metallised with aluminium.

The present description enables the person skilled in the art to use the invention comprehensively. Even without further comments, it is therefore assumed that a person skilled in the art will be able to utilise the above description in the broadest scope.

If anything should be unclear, it goes without saying that the cited publications and patent literature should be consulted. Accordingly, these documents are regarded as part of the disclosure content of the present description.

### Examples

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

Furthermore, it goes without saying to the person skilled in the art that, both in the examples given and also in the remainder of the description, the component amounts present in the compositions always add up only to 100% by weight or 100 mol %, based on the composition as a whole, and cannot exceed this, even if higher values could arise from the per cent ranges indicated. Unless indicated otherwise, % data are regarded as % by weight or mol %, with the exception of ratios, which are given in volume data.

The temperatures given in the examples and description and in the Claims are always in ° C.

### Example 1

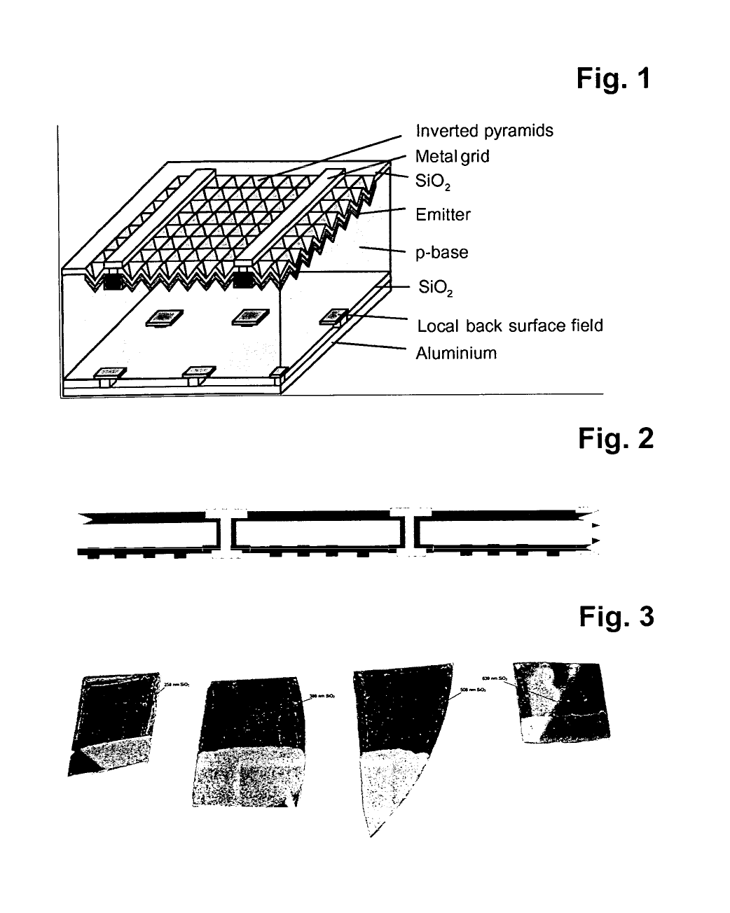

In accordance with Example 4 from the European patent application with the application number 11 001 920.5: 3 g of salicylic acid and 1 g of acetylacetone in 25 ml of isopropanol and 25 ml of diethylene glycol monoethyl ether are initially introduced in a 100 ml round-bottomed flask. 4.9 g of aluminium tri-sec-butoxide are added to the solution, and the mixture is stirred for a further 10 minutes. 5 g of acetic acid are added in order to neutralise the butoxide and adjust the pH of the ink, and the mixture is again stirred for 10 minutes. 1.7 g of water are added in order to hydrolyse the partially protected aluminium alkoxide, and the slightly yellow solution is stirred for 10 minutes and left to stand in order to age. The solids content can be increased to 6% by weight. The ink exhibits a stability of >3 months with ideal coating properties and efficient drying (cf. FIGS. 1 and 2 in the above-mentioned patent application 11 001 920.5).

In order to evaluate the metal-barrier action, multiple coatings each with a coating thickness of about 40 nm per individual coating are selected. Between each coating, drying is carried out for two minutes at 400° C. on a hotplate under atmospheric conditions. The multiple coatings are heat-treated again at 450° C., as described above, for 15 minutes. It is found here that penetration by the aluminium can be prevented from four individual coatings (total layer thickness 170 nm). It can be shown in a reference experiment with an ink having a higher concentration by weight (about 6% w/w) that a single coating with a final layer thickness of 165 nm also represents an effective metal barrier after drying for two minutes at 400° C.

### Example 2

In order to investigate a possible barrier action of SiO₂, 4 wafer pieces (Cz, p-type, polished on one side, 10 Ω*cm) are coated with SiO₂ in the sol-gel process by spin coating (optionally with multiple coating, if necessary, where each layer is thermally compacted in advance as described in Example 1) and various layer thicknesses, and the sol applied is thermally compacted (30 min at 450° C., as described in Example 1). Half of each wafer is etched free by an HF dip.

FIG. 3 shows photographs of the wafer pieces before metallisation.

An aluminium metal paste is subsequently applied to the entire surface of the wafer in a layer thickness of 20 μm by means of a hand coater, and the wafer treated in this way is fired for 100 s in a belt furnace having four zones (T set points: 850/800/800/800° C.). The aluminium paste is subsequently removed by etching with a phosphoric acid (85%)/nitric acid (69%)/acetic acid (100%) mixture (in v/v: 80/5/5, remainder water). The SiO₂ layer is then etched off with dilute HF.

In order to exclude the influence of the coating on the surface, a coated reference without printed-on metal paste is processed at the same time in each case.

After exposure of the silicon surface, the samples exhibit surface morphologies in the area not covered by SiO₂ which are typical of alloy formation of aluminium paste in silicon. Irrespective of the SiO₂ layer thickness already present, the areas covered by SiO₂ exhibit structures or etch figures which have a square and/or rectangular character. The reference samples processed at the same time have neither of the two features observed. Compared with the effect of the metal paste on the SiO₂ layers, no barrier action is observed.

Irrespective of the SiO₂ layer thickness produced, no barrier action of SiO₂ against the effect of the metal paste is accordingly observed.

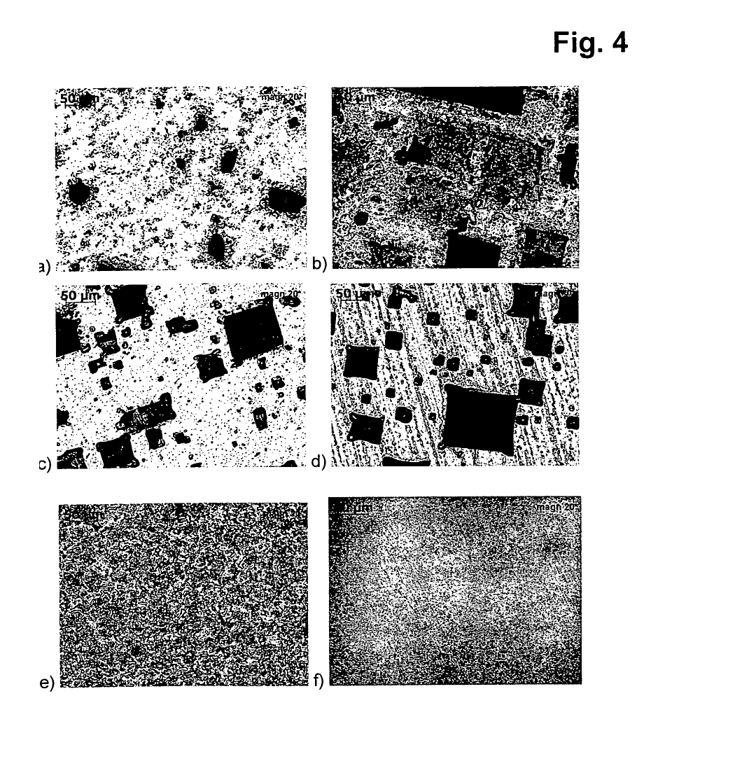

FIG. 4 shows photomicrographs of the surface after the etch treatment. The photographs show the surfaces of SiO₂-coated wafers after firing and subsequent etching-off of the aluminium paste (a 258 nm of SiO₂; b 386 nm of SiO₂; c 508 nm of SiO₂; d 639 nm of SiO₂; e no barrier; f reference without metal paste).

### Example 3

3 wafer pieces (Cz, p-type, polished on one side, 10 Ω*cm) are coated with a sol-gel-based Al₂O₃ layer by spin coating to give various layer thicknesses (optionally with multiple coating, if necessary, where each layer is thermally compacted in advance, as described under Example 1). The sol layer is thermally compacted (30 min at 450° C., as described under Example 1), and half of the Al₂O₃ layer is subsequently removed by etching with dilute HF solution.

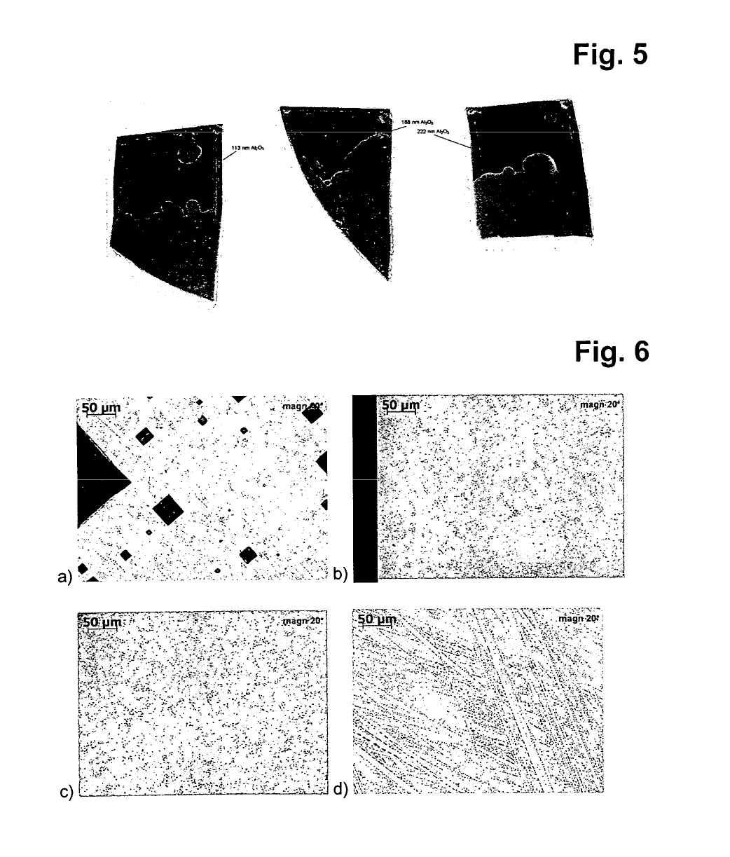

FIG. 5 shows photographs of the wafer pieces before metallisation.

An aluminium metal paste is subsequently applied to the entire surface of the wafer in a layer thickness of 20 μm by means of a hand coater, and the wafer is fired for 100 s in a belt furnace having four zones (T set points: 850/800/800/800° C.). After the firing process, the aluminium paste is removed by etching with a phosphoric acid (85%)/nitric acid (69%)/acetic acid (100%) mixture (in v/v: 80/5/5, remainder water). The Al₂O₃ layer and any parasitically formed SiO₂ are then etched off with dilute HF.

FIG. 6 shows photomicrographs of the surface after the etch treatment. The photomicrographs show the surfaces of Al₂O₃-coated wafers after firing and subsequent etching-off of the aluminium paste (a 113 nm of Al₂O₃; b 168 nm of Al₂O₃; c 222 nm of Al₂O₃; d reference wafer without metal paste).

In order to exclude the influence of the coating on the surface, a coated reference without printed-on metal paste is processed at the same time in each case.

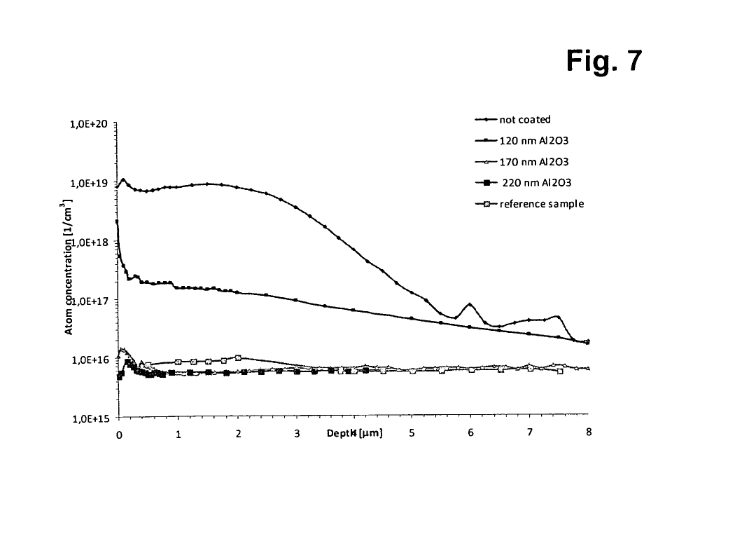

The sample which is covered with a layer thickness of 113 nm of Al₂O₃ exhibits a surface structure which can be attributed to attack by the aluminium paste. Square to rectangular structures, pits and etching trenches can be discovered in the silicon surface. The aluminium paste “spiked” through the Al₂O₃ layer. As soon as the layer thickness of the Al₂O₃ exceeds 170 nm, the base doping of the silicon wafer is exclusively determined by means of electrochemical capacitance/voltage measurements (ECV). This is 1*10¹⁶ boron atoms/cm³ (cf. FIG. 7).

From an oxide thickness of ˜170 nm, a clear barrier action can be detected. This is illustrated by electrocapacitance measurements (ECV) in FIG. 7.

FIG. 7 shows ECV measurements of the samples coated with various layer thicknesses, an uncoated reference sample and a reference processed at the same time, but not metallised with aluminium. At the point passivated with 170 and 220 nm of Al₂O₃, only the base doping (boron ˜1*10¹⁶ atoms/cm³) can be detected. The positive charge carriers in the silicon were measured.

In a reference experiment (coating conditions in accordance with Example 2c), it can be shown that the coating does not necessarily have to be compacted completely in order to achieve a barrier action (barrier action after 2 min with drying at 350° C.).

1. Process for the production of a dielectric layer which acts as passivation layer and diffusion barrier against aluminium and/or other related metals and metal pastes, characterised in that an aluminium oxide sol or an aluminium oxide hybrid sol in the form of an ink or paste is applied over the entire surface or in a structured manner and is compacted and dried by warming at elevated temperatures, forming amorphous Al₂O₃ and/or aluminium oxide hybrid layers.

2. Process according to claim 1, characterised in that amorphous Al₂O₃ and/or aluminium oxide hybrid layers having a thickness of <100 nm are formed.

3. Process according to claim 1, characterised in that the aluminium oxide sol or aluminium oxide hybrid sol is applied and dried a number of times in order to form an amorphous Al₂O₃ and/or aluminium oxide hybrid layer having a thickness of at least 150 nm.

4. Process according to claim 1, characterised in that the drying is carried out at temperatures between 300 and 1000° C., preferably in the range between 350 and 450° C.

5. Process according to claim 1, characterised in that the drying of an applied layer is carried out within a time of two to five minutes.

6. Process according to claim 1, characterised in that the applied and dried layer(s) is (are) passivated by subsequent annealing at 400 to 500° C. in a nitrogen and/or forming-gas atmosphere.

7. Process according to claim 1, characterised in that aluminium oxide inks or aluminium oxide pastes based on the sol-gel process are applied which comprise at least one precursor, serving for doping, for the formation of an oxide of boron, gallium, silicon, germanium, zinc, tin, phosphorus, titanium, zirconium, yttrium, nickel, cobalt, iron, cerium, niobium, arsenic or lead.

8. Process according to claim 1, characterised in that boron doping of a silicon layer is carried out by drying an applied layer of a boron-containing aluminium oxide ink or paste at elevated temperature.

9. Process according to claim 8, characterised in that boron doping is carried out with emitter formation in the silicon.

10. Process according to claim 1, characterised in that phosphorus doping of a silicon layer is carried out by drying an applied layer of a phosphorus-containing aluminium oxide ink or paste at elevated temperature.

11. Dielectric aluminium oxide layer having passivation properties for p-doped base layers, obtainable by a process according to claim 1.

12. Dielectric layer which acts as diffusion barrier against aluminium and other related metals, obtainable by a process according to claim 1.
